(19) United States
(12) Patent Application Publication
(10) Pub. No.: US 2026/0314271 A1
(43) Pub. Date: Oct. 8, 2026

(54) SEMICONDUCTOR DEVICE AND METHOD FOR FORMING THE SAME

(71) Applicant: Taiwan Semiconductor Manufacturing Company, Ltd., Hsinchu (TW)

(72) Inventors: Sheng-Han Yi, Hsinchu City (TW); Hai-Dang Trinh, Hsinchu (TW); Yao-Wen Chang, Taipei (TW)

(21) Appl. No.: 19/280,674

(22) Filed: Jul. 25, 2025

Related U.S. Application Data
(60) Provisional application No. 63/782,663, filed on Apr. 3, 2025.

(51) Int. Cl. H10N 70/00; H10N 70/20

(52) U.S. Cl. CPC H10N 70/8613; H10N 70/021; H10N 70/063; H10N 70/231; H10N 70/823

(57) ABSTRACT

The present disclosure is directed towards an integrated chip. The integrated chip includes a first dielectric layer over a substrate. A phase change material (PCM) structure is over the first dielectric layer. A heater structure is in the first dielectric layer and under the PCM structure. The heater structure includes a first buffer layer and a first conductive layer on the first buffer layer. The first conductive layer comprises a metal. The first buffer layer comprises the metal and a first element different from the metal. A first atomic percent of the first element in the first buffer layer is greater than a second atomic percent of the metal in the first buffer layer.

### REFERENCE TO RELATED APPLICATION

This Application claims the benefit of U.S. Provisional Application No. 63/782,663 filed on Apr. 3, 2025, the contents of which are hereby incorporated by reference in their entirety.

### BACKGROUND

Radio frequency (RF) switches are devices used to route high frequency signals and are commonly used in wireless communication systems. For example, RF switches may be found in cell phones, WiFi routers, and so on. Compared to complementary metal-oxide semiconductor (CMOS) switches, RF switches generally have higher power handling, better linearity, and a wider frequency band of operation.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of various features may be arbitrarily increased or reduced for clarity of discussion.

FIG. 1 illustrates a cross-sectional view of some embodiments of an integrated chip including a phase change material (PCM) switch with a heater structure having a buffer layer.

FIG. 2 illustrates a top view of some embodiments of the integrated chip of FIG. 1.

FIG. 3 illustrates a cross-sectional view of some other embodiments of the integrated chip of FIG. 1.

FIG. 4 illustrates a perspective view of some embodiments of the PCM switch of FIG. 1.

FIG. 5A illustrates a cross-sectional view of some embodiments of an integrated chip including a PCM switch with a heater structure having a buffer layer.

FIGS. 5B and 5C illustrate cross-sectional views of some other embodiments of the integrated chip of FIG. 5A.

FIG. 6 illustrates a cross-sectional view of some embodiments of a section of the heater structure of FIG. 5A.

FIG. 7 illustrates a cross-sectional view of some embodiments of an integrated chip including a PCM switch arranged in an interconnect structure.

FIGS. 8-19 illustrate a series of cross-sectional views of some embodiments of a method of forming an integrated chip including a PCM switch with a heater structure having a buffer layer.

FIG. 20 illustrates a block diagram of some embodiments of a method of forming an integrated chip including a PCM switch with a heater structure having a buffer layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

A phase change material (PCM) switch includes a first electrode, a second electrode, and a PCM structure laterally between the first and second electrodes. The PCM switch may further include a heater structure under the PCM structure. The PCM structure has a crystalline phase and an amorphous phase with different electrical resistivity values. The heater structure is configured to selectively heat the PCM structure and selectively change the PCM structure between the crystalline phase and the amorphous phase. When in the crystalline phase, the PCM structure is in a low resistance state that electrically couples the first and second electrodes together. When in the amorphous phase, the PCM structure is in a high resistance state that electrically isolates the first and second electrodes from one another. The low resistance state may correspond to an “ON” state of the PCM switch and the high resistance state may correspond to an “OFF” state of the PCM switch.

The heater structure is arranged in a dielectric layer of an interconnect structure over a substrate of an integrated chip. The interconnect structure includes conductive interconnects (e.g., wires and/or vias) coupled to one or more devices (e.g., transistors) on the substrate. The heater structure includes a conductive layer that comprises a first metal (e.g., tungsten). The PCM switch may face performance issues due to high electrical resistance in the heater structure. This issue may occur because the conductive layer comprising the first metal (e.g., tungsten) is deposited directly on a lower dielectric layer, which may result in the formation of relatively small grain sizes in the conductive layer. The smaller grain sizes increase electron scattering, thereby raising the electrical resistance of the heater structure. As a result, the heater structure may not generate sufficient heat (e.g., heat above a melting point of the PCM structure) to switch the PCM structure into the amorphous state. This issue is exacerbated in low power applications. Additionally, during deposition of the conductive layer, an RF generator may be biased at a relatively high power (e.g., between 50 to 300 Watts (W)) to generate a plasma in a processing chamber that the conductive layer is formed in. The conductive layer coats the interconnect structure over the substrate, and the relatively high power may cause plasma-induced damage (PID) to the one or more devices on the substrate. For example, the high power during the deposition of the conductive layer may lead to charge accumulation in the conductive interconnects. This charge accumulation may result in leakage current or device failure, such as breakdown of gate dielectric layers in the one or more devices. Thus, a performance and/or a yield of the integrated chip may be reduced.

Various embodiments of the present disclosure are directed towards an integrated chip including a PCM switch with a heater structure that has low resistivity. The PCM switch includes a first electrode, a second electrode, and a PCM structure disposed laterally between the first and second electrodes. The PCM switch further includes a heater structure spaced laterally between the first and second electrodes. The heater structure comprises a buffer layer and a conductive layer over the buffer layer. In some embodiments, the conductive layer comprises a first metal (e.g., tungsten), and the buffer layer comprises a nitride (e.g., tungsten nitride) of the first metal with a relatively low concentration of nitrogen (e.g., a content of nitrogen in the buffer layer is less than 50 at %). The relatively low concentration of nitrogen in the buffer layer facilitates the buffer layer providing a good structural foundation for the conductive layer, such that the conductive layer has relatively large grain sizes (e.g., grain sizes larger than a tungsten layer deposited on a dielectric). The relatively large grain sizes of the conductive layer decrease electron scattering and reduce a resistivity of the heater structure.

Further, during fabrication of the heater structure, the buffer layer is deposited followed by the conductive layer in a single processing chamber. During this process, a carrier gas (e.g., argon) and a precursor gas (e.g., nitrogen) are flowed in the processing chamber. A deposition process (e.g., a physical vapor deposition (PVD)) is performed to deposit the buffer layer. After the buffer layer is deposited, the flow of the precursor gas is stopped, but flowing of the carrier gas is continued and the conductive layer is deposited (e.g., by PVD) over the buffer layer. The precursor gas (e.g., nitrogen) reduces a plasma sheath potential over the substrate and decreases bombardment from the carrier gas, thereby decreasing PID. Thus, the buffer layer mitigates PID-related issues to underlying devices on the substrate, thereby increasing a performance and/or yield of the integrated chip.

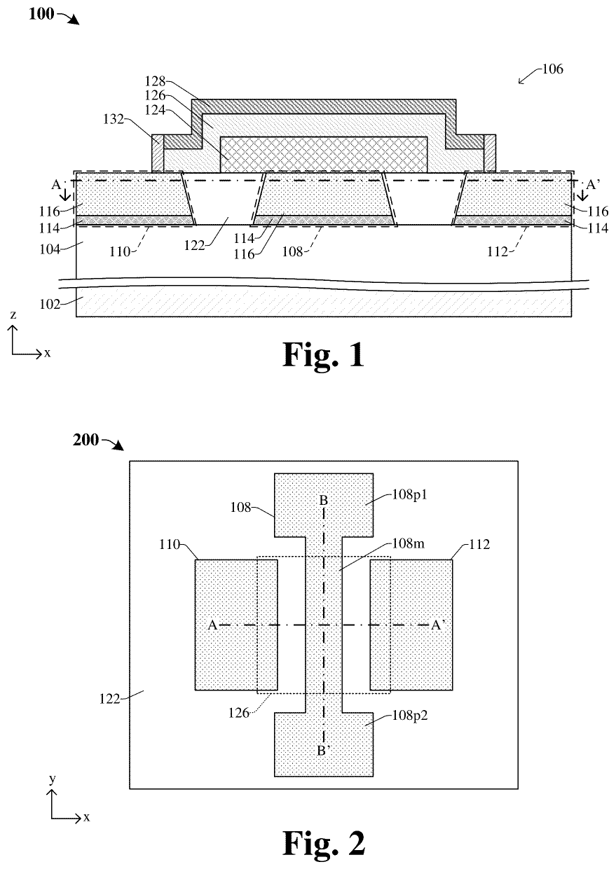

FIG. 1 illustrates a cross-sectional view 100 of some embodiments of an integrated chip including a phase change material (PCM) switch 106 with a heater structure 108 comprising a buffer layer 114. The PCM switch 106 may be referred to as a PCM device, a PCM radio frequency (RF) switch, a semiconductor device, or the like.

The PCM switch 106 overlies a first dielectric layer 104 that is over a substrate 102. In some embodiments, the PCM switch 106 comprises a heater structure 108, a first electrode 110, a second electrode 112, a thermal barrier structure 124, and a PCM structure 126. The heater structure 108 is disposed in a second dielectric layer 122. The thermal barrier structure 124 is arranged between the heater structure 108 and the PCM structure 126.

The first and second electrodes 110, 112 are disposed in the second dielectric layer 122 on opposing sides of the heater structure 108. The first electrode 110 is laterally offset from a first side of the heater structure 108 and the second electrode 112 is laterally offset from a second side of the heater structure 108. In some embodiments, the PCM structure 126 continuously extends from a top surface of the first electrode 110, over the heater structure 108, to a top surface of the second electrode 112. A hard mask 128 overlies the PCM structure 126. A sidewall spacer 132 is disposed along sidewalls of the PCM structure 126 and sidewalls of the hard mask 128.

The PCM structure 126 is configured to change between a high resistance state and a low resistance state by changing between different phases. In some embodiments, the PCM structure 126 is in the high resistance state when the PCM structure 126 has an amorphous phase and the PCM structure is in the low resistance state when the PCM structure 126 has a crystalline phase. In various embodiments, when at least a portion of the PCM structure 126 (e.g., in a region above the heater structures 108) is in the amorphous phase, the PCM structure 126 is in the high resistance state. In further embodiments, when the PCM structure 126 is in the crystalline phase, the PCM structure 126 is in the low resistance state.

The high resistance state may correspond to an “OFF” state for the PCM switch 106, and the low resistance state may correspond to an “ON” state for the PCM switch. In some embodiments, when the PCM structure 126 is in the high resistance state the first and second electrodes 110, 112 are electrically isolated from one another, and when the PCM structure 126 is in the low resistance state the first and second electrodes 110, 112 are electrically coupled to one another. The phase of the PCM structure 126 may be adjusted by heating the PCM structure 126. The heater structure 108 is configured to selectively heat the PCM structure 126 to selectively change the PCM structure 126 between the amorphous phase and the crystalline phase. For example, the PCM structure 126 may be set to the amorphous phase by heating the PCM structure 126 to a first temperature (e.g., a melting temperature of the PCM structure 126) for a first duration and subsequently cooling the PCM structure 126. In another example, the PCM structure 126 may be set to the crystalline phase by heating the PCM structure 126 to at least a second temperature (e.g., a crystalline temperature of the PCM structure 126), while staying below the first temperature, for a second duration greater than the first duration.

In some embodiments, the heater structure 108, the first electrode 110, and the second electrode 112 each comprise a buffer layer 114 and a conductive layer 116 on the buffer layer 114. The buffer layer 114 is configured to provide a good atomic structural foundation for the conductive layer 116 to have a relatively low resistivity, such that a resistivity of the heater structure 108 is reduced. As a result, an ability for the heater structure 108 to selectively heat the PCM structure 126 is improved and a power consumption of the PCM switch 106 is reduced. Further, the first and second electrodes 110, 112 each comprising the buffer layer 114 and the conductive layer 116 reduce resistivities of the first and second electrodes 110, 112, thereby further reducing power consumption of the PCM switch 106.

In various embodiments, the conductive layer 116 comprises a first metal (e.g., tungsten) and the buffer layer 114 comprises a nitride of the first metal (e.g., tungsten nitride). In various embodiments, a chemical content of nitrogen in the buffer layer 114 is relatively low (e.g., equal to or less than 18 atomic percent (at %)). In some embodiments, a thickness of the buffer layer 114 is relatively low (e.g., equal to or less than 400 angstroms) and less than a thickness of the conductive layer 116. The buffer layer 114 having the relatively low chemical content of nitrogen and the relatively low thickness facilitates providing the good atomic structural foundation for the conductive layer 116. As a result, the conductive layer 116 may have a crystalline structure with relatively large grain sizes. For example, the conductive layer 116 has larger grain sizes compared to another conductive layer (not shown) comprising the first metal (e.g., tungsten) that is directly on the first dielectric layer 104. Accordingly, the heater structure 108 comprising the conductive layer 116 on the buffer layer 114 reduces a resistivity of the heater structure 108 (e.g., to about 8.8 μΩ*cm). Thus, the PCM switch 106 has improved device performance (e.g., lower operating voltages, lower power consumption, etc.).

In addition, the buffer layer 114 may be configured to mitigate issues during fabrication of the integrated chip. For example, the buffer layer 114 may mitigate issues caused by plasma-induced damage (PID) to one or more devices (not shown) on the substrate 102. As a result, leakage current in the one or more devices and/or a breakdown of gate dielectrics of the one or more devices may be prevented or reduced, thereby increasing a performance and/or yield of the integrated chip.

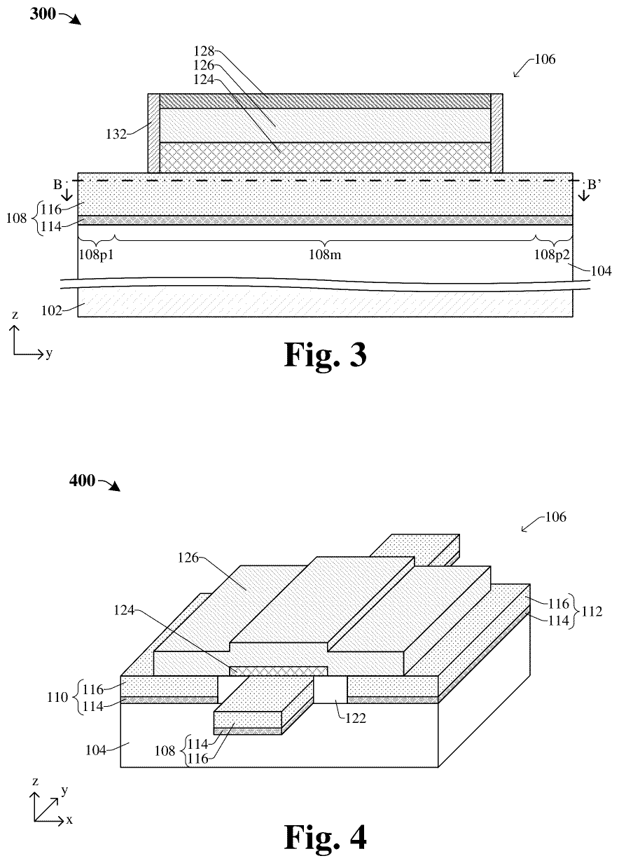

FIG. 2 illustrates a top view 200 of some embodiments of the integrated chip of FIG. 1. The cross-sectional view 100 of FIG. 1 may, for example, be taken along line A-A′ in FIG. 2.

As illustrated in the top view 200, the heater structure 108 comprises a first pad segment 108p1, a second pad segment 108p2, and a middle segment 108m continuously extending between the first and second pad segments 108p1, 108p2. The first electrode 110 and the second electrode 112 are spaced on opposing sides of the middle segment 108m of the heater structure 108. In some embodiments, widths of the first and second pad segments 108p1, 108p2 are each less than a width of the middle segment 108m. The PCM structure 126 is represented in phantom in the top view 200. The PCM structure 126 continuously laterally extends from the first electrode 110, over the middle segment 108m of the heater structure 108, to the second electrode 112.

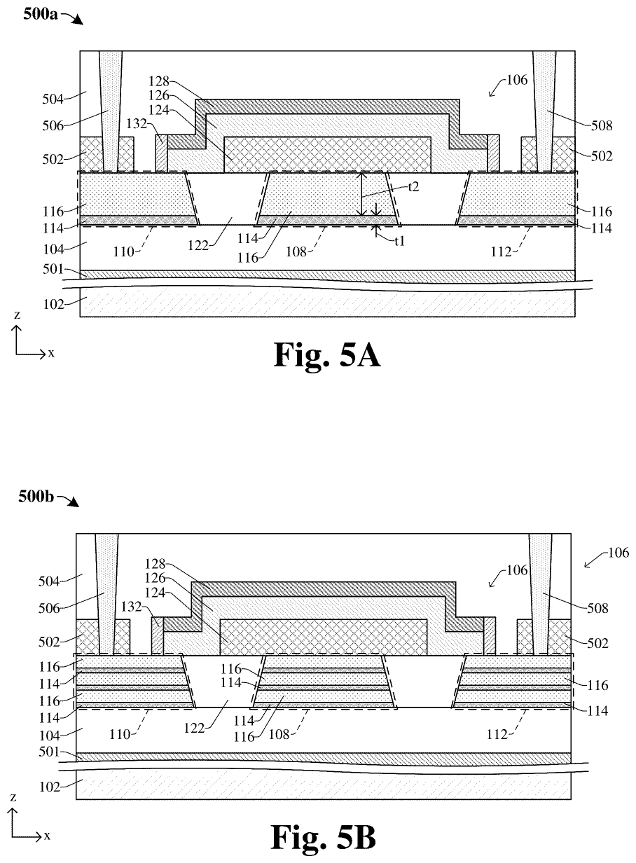

FIG. 3 illustrates a cross-sectional view 300 of some other embodiments of the integrated chip of FIG. 1. The cross-sectional view 300 of FIG. 3 may, for example, be taken along line B-B′ in FIG. 2. The cross-sectional view 100 of FIG. 1 is taken along a first direction (e.g., along the x-axis) and the cross-sectional view 300 of FIG. 3 is taken along a second direction (e.g., along the y-axis) orthogonal to the first direction.

As illustrated in the cross-sectional view 300, the PCM structure 126 extends along the middle segment 108m of the heater structure 108. The PCM structure 126 is spaced laterally between the first and second pad segments 108p1, 108p2. In some embodiments, outer sidewalls of the thermal barrier structure 124, outer sidewalls of the PCM structure 126, and outer sidewalls of the hard mask 128 are aligned with one another. In various embodiments, the sidewall spacer 132 extends along the outer sidewalls of the thermal barrier structure 124, the outer sidewalls of the PCM structure 126, and the outer sidewalls of the hard mask 128.

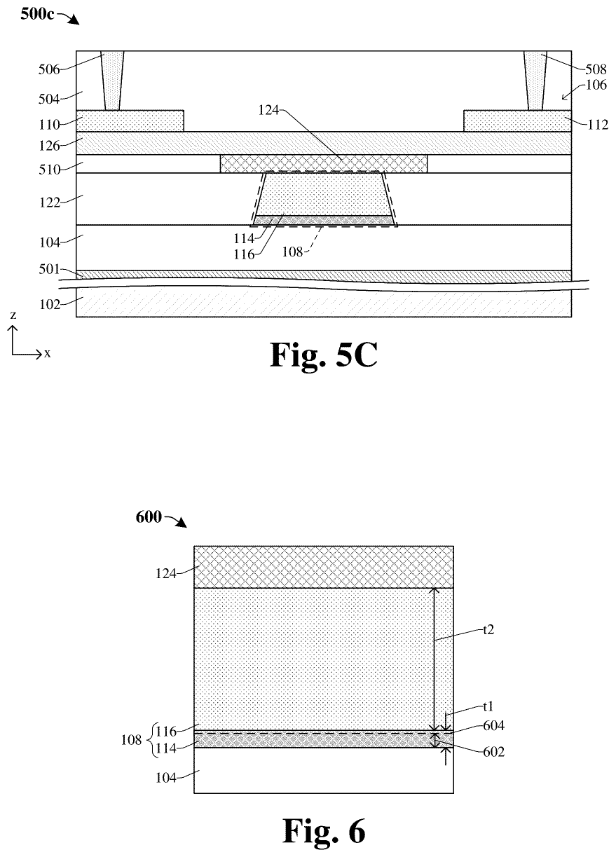

FIG. 4 illustrates a perspective view 400 of some embodiments of the PCM switch 106 of FIG. 1.

As illustrated in the perspective view 400, the thermal barrier structure 124 vertically separates the PCM structure 126 from the heater structure 108. The PCM structure 126 overlies a top surface of and extends along opposing sidewalls of the thermal barrier structure 124. The PCM structure 126 directly contacts at least a portion of a top surface of the first electrode 110 and at least a portion of a top surface of the second electrode 112. The PCM structure 126 continuously laterally extends in a first direction (e.g., along the x-axis) between the first and second electrodes 110, 112. The heater structure 108 is elongated in a second direction (e.g., along the y-axis) and underlies the PCM structure 126.

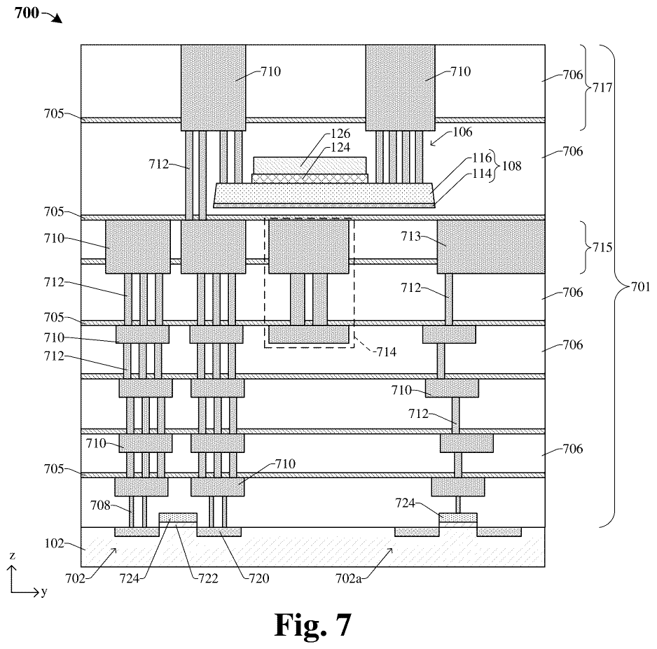

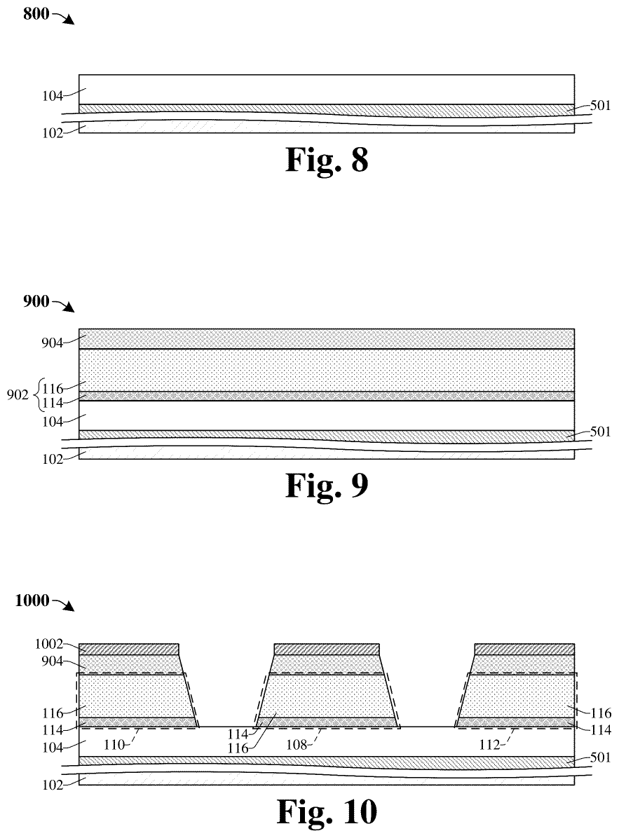

FIG. 5A illustrates a cross-sectional view 500a of some embodiments of an integrated chip including a PCM switch 106 with a heater structure 108 comprising a buffer layer 114.

The integrated chip includes an etch stop layer 501 over a substrate 102. A first dielectric layer 104 overlies the etch stop layer 501. The PCM switch 106 overlies the first dielectric layer 104. The substrate 102 may, for example, be or comprise silicon, monocrystalline silicon, a bulk substrate, a silicon-on-insulator (SOI) substrate, some other suitable substrate, or the like. The etch stop layer 501 may, for example, be or comprise silicon carbide, silicon nitride, some other suitable dielectric, or any combination of the foregoing. In some embodiments, a thickness of the etch stop layer 501 is about 750 angstroms, within a range of about 600 to 900 angstroms, or some other suitable value. In some embodiments, the first dielectric layer 104 may, for example, be an oxide (e.g., silicon dioxide), a low-k dielectric, some other suitable dielectric material, or any combination of the foregoing. As used herein, a low-k dielectric is a dielectric having a dielectric constant less than 3.9. In some embodiments, a thickness of the first dielectric layer 104 is about 500 angstroms, within a range of about 400 to 600 angstroms, or some other suitable value.

The PCM switch 106 comprises a heater structure 108, a first electrode 110, a second electrode 112, a thermal barrier structure 124, and a PCM structure 126. The heater structure 108 is disposed in a second dielectric layer 122. The first and second electrodes 110, 112 are disposed in the second dielectric layer 122 on opposing sides of the heater structure 108. In various embodiments, the first electrode 110 is laterally offset from a first side of the heater structure 108 and the second electrode 112 is laterally offset from a second side of the heater structure 108. In some embodiments, the first electrode 110 is electrically isolated from the heater structure 108 and the second electrode 112 is electrically isolated from the heater structure 108.

The thermal barrier structure 124 overlies the heater structure 108. The PCM structure 126 overlies the thermal barrier structure 124 and overlies the first and second electrodes 110, 112. In some embodiments, the PCM structure 126 extends along opposing sidewalls of the thermal barrier structure 124. A hard mask 128 overlies the PCM structure 126. A sidewall spacer 132 extends along sidewalls of the PCM structure 126 and sidewalls of the hard mask 128.

In some embodiments, the second dielectric layer 122 may, for example, be or comprise an oxide (e.g., silicon dioxide), a low-k dielectric, some other suitable dielectric material, or any combination of the foregoing. The thermal barrier structure 124 may, for example, be or comprise silicon nitride, silicon carbide, aluminum nitride, some other suitable material, or any combination of the foregoing. The thermal barrier structure 124 is configured to facilitate a uniform distribution of heat from the heater structure 108 to the PCM structure 126, thereby increasing a switching performance of the PCM switch 106. The PCM structure 126 may, for example, be or comprise germanium antimony telluride, germanium telluride, vanadium oxide, some other suitable phase change material, or any combination of the foregoing. The hard mask 128 may, for example, be or comprise silicon nitride, silicon carbide, some other suitable dielectric, or any combination of the foregoing. The sidewall spacer 132 may, for example, be or comprise silicon nitride, silicon carbide, some other suitable dielectric, or any combination of the foregoing.

A passivation layer 502 overlies the first electrode 110 and the second electrode 112. In some embodiments, the passivation layer 502 and the thermal barrier structure 124 comprise a same material (e.g., silicon nitride, silicon carbide, aluminum nitride, etc.). A third dielectric layer 504 overlies the hard mask 128 and the passivation layer 502. In some embodiments, the third dielectric layer 504 may, for example, be or comprise an oxide (e.g., silicon dioxide), a low-k dielectric, some other suitable dielectric, or any combination of the foregoing. A first conductive via 506 and a second conductive via 508 are arranged in the third dielectric layer 504. The first conductive via 506 is electrically coupled to the first electrode 110 and the second conductive via 508 is electrically coupled to the second electrode 112. The first and second conductive vias 506, 508 may, for example, be or comprise copper, aluminum, aluminum copper, some other suitable conductive material, or any combination of the foregoing.

In some embodiments, the heater structure 108 and the first and second electrodes 110, 112 each comprise a buffer layer 114 and a conductive layer 116 on the buffer layer 114. In some embodiments, the buffer layer 114 directly contacts a top surface of the first dielectric layer 104 and the conductive layer 116 directly contacts a top surface of the buffer layer 114. The buffer layer 114 is configured to reduce an electrical resistance of the heater structure 108 and/or mitigate issues (e.g., issues due to PID) during fabrication of the PCM switch 106.

In some embodiments, the conductive layer 116 may, for example, be or comprise a first metal (e.g., tungsten, molybdenum, etc.) or some other suitable material. In some embodiments, the buffer layer 114 may, for example, be or comprise a nitride of the first metal (e.g., tungsten nitride, molybdenum nitride, etc.) or some other suitable material. Accordingly, in some embodiments, the buffer layer 114 comprises the first metal (e.g., tungsten) and a first element (e.g., nitrogen) different from the first metal. In various embodiments, a first atomic percent of nitrogen in the buffer layer 114 is less than a second atomic percent of the first metal in the buffer layer 114. In some embodiments, the first atomic percent of nitrogen in the buffer layer 114 is about 1 at %, about 1.5 at %, within a range of about 0.5 at % to 8.5 at %, within a range of about 8.5 at % to 18 at %, within a range of about 0.5 at % to 18 at %, or some other suitable value. In various embodiments, the buffer layer 114 comprises the first metal (e.g., tungsten) and the first element (e.g., nitrogen), where the first metal (e.g., tungsten) constitutes a majority of a chemical composition of the buffer layer 114. In some embodiments, the chemical content of the first metal (e.g., tungsten) in the buffer layer 114 is greater than 50 at %. In some embodiments, a first thickness t1 of the buffer layer 114 is relatively low (e.g., equal to or less than about 400 angstroms) and less than a second thickness t2 of the conductive layer 116. In various embodiments, an atomic percent of the first metal in the conductive layer 116 is greater than the first atomic percent of nitrogen in the buffer layer 114. In yet further embodiments, the atomic percent of the first metal in the conductive layer 116 is greater than the second atomic percent of the first metal in the buffer layer 114. In some embodiments, the conductive layer 116 has a crystalline structure and may have columnar gains, and the buffer layer 114 has an amorphous structure. In further embodiments, the conductive layer 116 has a crystalline structure and the buffer layer 114 has a polycrystalline structure. In yet further embodiments, the buffer layer 114 may have a crystalline structure with grain sizes smaller than the grain sizes of the conductive layer 116. In various embodiments, the buffer layer 114 may be configured and/or referred to as a seed layer. The conductive layer 116 may, for example, be or comprise tungsten, molybdenum, tantalum, or the like. The buffer layer 114 may, for example, be or comprise tungsten nitride, molybdenum nitride, tantalum nitride, or the like.

By virtue of the first atomic percent of nitrogen being less than the second atomic percent of the first metal in the buffer layer 114 and the relatively low first thickness t1 of the buffer layer 114, the buffer layer 114 may provide a good atomic structural foundation for the conductive layer 116 to have a crystalline structure with relatively large grain sizes. As a result, the conductive layer 116 has a low electrical resistivity and an overall electrical resistivity of the heater structure 108 is relatively low (e.g., less than about 10 μΩ*cm, about 8.8 μΩ*cm, etc.). Accordingly, voltages applied to the heater structure 108 to generate enough heat to selectively switch the phase of the PCM structure 126 (e.g., switch between the crystalline phase and the amorphous phase) may be reduced. For example, voltages needed for the heater structure 108 to generate enough heat to selectively switch the phase of the PCM structure 126 are lower than voltages needed for another heater structure (e.g., that does not comprise the buffer layer 114) to selectively switch the phase of a PCM structure.

In some embodiments, the first atomic percent of nitrogen in the buffer layer 114 being non-zero or greater than or equal to about 0.5 at % mitigates plasma-induced damage (PID) to one or more devices (e.g., transistors) on the substrate 102 during fabrication of the PCM switch 106. Accordingly, a yield and overall performance of the integrated chip is increased. In some embodiments, the first atomic percent of nitrogen in the buffer layer 114 being about 18 at % or less mitigates issues due to PID while providing a good atomic foundation for the conductive layer 116 to have relatively large grain sizes and a low electrical resistance. For example, the first atomic percent of nitrogen in the buffer layer 114 being about 18 at % or less, then the conductive layer 116 may have larger grain sizes compared to another conductive layer (e.g., comprising tungsten) disposed directly on the first dielectric layer 104. As a result, the overall electrical resistivity of the heater structure 108 is relatively low (e.g., less than about 10 μΩ*cm). In yet further embodiments, if the first atomic percent of nitrogen in the buffer layer 114 is greater than about 18 at %, then the conductive layer 116 may have relatively small grain sizes and an overall electrical resistivity of the heater structure 108 may, for example, be equal to or greater than 10.3 μΩ*cm.

In some embodiments, the conductive layer 116 is substantially free of the first element (e.g., nitrogen). In further embodiments, the conductive layer 116 is devoid of the first element (e.g., nitrogen). In yet further embodiments, an atomic percentage of the first element (e.g., nitrogen) in the conductive layer 116 is less than that of the first atomic percentage of the first element (e.g., nitrogen) in the buffer layer 114. In various embodiments, a bottom region of the conductive layer 116 (e.g., a region that spans 1/10^{th} or less of the second thickness t2 of the conductive layer 116 and starts from a bottom surface of the conductive layer 116) may comprise a non-zero atomic percent (e.g., about 1 at % or less) of the first element (e.g., nitrogen) that is less than the first atomic percentage of the first element in the buffer layer 114. In such embodiments, a top region of the conductive layer 116 (e.g., a remaining portion of the conductive layer 116 above the bottom region) may be devoid of the first element.

In further embodiments, the buffer layer 114 has a first molar percentage of nitrogen that is less than a second molar percentage of the first metal (e.g., tungsten). In various embodiments, the first molar percentage of nitrogen in the buffer layer 114 is equal to or less than about 18 mol %, about 1 mol %, within a range of about 1 mol % to about 18 mol %, or some other suitable value.

In some embodiments, the first thickness t1 of the buffer layer 114 is within a range of about 10 to 400 angstroms, equal to or less than about 400 angstroms, within a range of about 10 to 200 angstroms, within a range of about 200 to 400 angstroms, or some other suitable value. In some embodiments, the first thickness t1 of the buffer layer 114 being equal to or greater than 10 angstroms facilitates the buffer layer 114 providing a good atomic foundation for the conductive layer 116 to have a low electrical resistance and mitigates issues during fabrication of the heater structure 108 (e.g., issues related to PID). In further embodiments, the first thickness t1 of the buffer layer 114 being equal to or less than about 400 angstroms facilitates the overall electrical resistivity of the heater structure 108 being relatively low. In some embodiments, a resistivity of the buffer layer 114 is less than or equal to about 140 μΩ*cm. In further embodiments, a resistivity of the conductive layer 116 is less than the resistivity of the buffer layer 114. In some embodiments, the resistivity of the conductive layer 116 is within a range of about 10 to 13 μΩ*cm, less than about 10 μΩ*cm, or some other suitable value. In some embodiments, the second thickness is about 1,000 angstroms, within a range of about 600 to 2,500 angstroms, or some other suitable value.

In various embodiments, by virtue of the first atomic percent of nitrogen in the buffer layer 114 being about 18 at % or less and the first thickness t1 being about 400 angstroms or less, resistivities of the heater structure 108, the first electrode 110, and the second electrode 112 are relatively low (e.g., equal to or less than about 10 μΩ*cm or are about 8.8 μΩ*cm). The first electrode 110 and the second electrode 112 comprising the buffer layer 114 and the conductive layer 116 decreases resistivities of the first and second electrodes 110, 112 and may decrease fabrication costs. For example, in some embodiments, the first and second electrodes 110, 112 are formed concurrently with the heater structure 108, thereby decreasing fabrication costs. Therefore, the heater structure 108 comprising the conductive layer 116 over the buffer layer 114 reduces a power consumption of the PCM switch 106, mitigates issues (e.g., due to PID) during fabrication of the PCM switch 106, and increases an overall performance of the integrated chip.

FIG. 5B illustrates a cross-sectional view 500b of some other embodiments of the integrated chip of FIG. 5A.

In some embodiments, the heater structure 108, the first electrode 110, and the second electrode 112 each comprise a plurality of buffer layers 114 and a plurality of conductive layers 116 alternatingly stacked with the plurality of buffer layers 114. By alternatingly stacking the plurality of buffer layers 114 with the plurality of conductive layers 116, resistivities of the heater structure 108, the first electrode 110, and the second electrode 112 may be reduced.

FIG. 5C illustrates a cross-sectional view 500c of some other embodiments of the integrated chip of FIG. 5A.

The heater structure 108 is arranged under a bottom surface of the PCM structure 126. An insulator layer 510 overlies the second dielectric layer 122 and is arranged on opposing sides of the thermal barrier structure 124. In some embodiments, the first electrode 110 and the second electrode 112 are arranged over the PCM structure 126. Accordingly, the first and second electrodes 110, 112 are vertically above the heater structure 108. The heater structure 108 is spaced laterally between the first and second electrodes 110, 112. In some embodiments, the first and second electrodes 110, 112 directly contact a top surface of the PCM structure 126.

In some embodiments, the first and second electrodes 110, 112 may comprise a material different from that of the buffer layer 114 and/or the conductive layer 116 of the heater structure 108. In various embodiments, the first and second electrodes 110, 112 may, for example, each be or comprise a metal (e.g., iridium, ruthenium, or the like), a metal nitride (e.g., titanium nitride, tantalum nitride), some other conductive material, or any combination of the foregoing. In some embodiments, the first and second electrodes 110, 112 may each include a single conductive layer that may, for example, comprise iridium, ruthenium, titanium nitride, tantalum nitride, or the like. In various embodiments, a thickness of the first electrode 110 is less than a thickness of the heater structure 108 and a thickness of the second electrode 112 is less than the thickness of the heater structure 108. In further embodiments, electrical resistivities of the first and second electrodes 110, 112 are greater than that of the heater structure 108. In yet further embodiments, the first and second electrodes 110, 112 may respectively comprise a second buffer layer (not shown) and a second conductive layer (not shown) over the second buffer layer. In such embodiments, the second buffer layer and the second conductive layer are respectively configured as the buffer layer 114 and the conductive layer 116 (e.g., as illustrated and/or described in FIG. 5A).

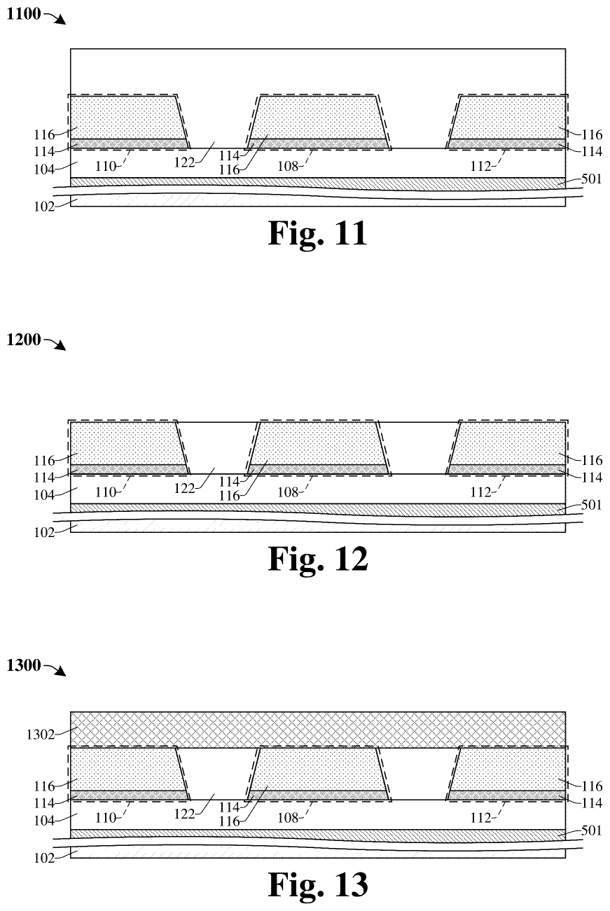

FIG. 6 illustrates a cross-sectional view 600 of some embodiments of a section of the heater structure 108 of FIG. 5A.

In some embodiments, the buffer layer 114 has a constant or substantially constant concentration of the first element (e.g., nitrogen) across the first thickness t1 of the buffer layer 114. In further embodiments, the buffer layer 114 has a constant or substantially constant concentration of the first element (e.g., nitrogen) across a first vertical distance 602 that extends from a bottom surface of the buffer layer 114 to a horizontal line 604. The horizontal line 604 is closer to a top surface of the buffer layer 114 than the bottom surface of the buffer layer 114. In various embodiments, the first vertical distance 602 corresponds to about 90% to 98% of the first thickness t1 of the buffer layer 114. In various embodiments, the concentration of the first element (e.g., nitrogen) in an upper region of the buffer layer 114 continuously decreases from the horizontal line 604 to the top surface of the buffer layer 114. In such embodiments, the upper region is defined between the horizontal line 604 and the top surface of the buffer layer 114. In yet further embodiments, the buffer layer 114 comprises a first layer defined across the first vertical distance 602 and a second layer defined between the horizontal line 604 and a bottom surface of the conductive layer 116. In such embodiments, the first layer has a constant or substantially constant concentration of the first element (e.g., nitrogen) across its thickness, and the second layer has a decreasing concentration of the first element (e.g., nitrogen) from a bottom surface of the second layer in a direction towards the conductive layer 116. Further, a thickness of the first layer is greater than a thickness of the second layer.

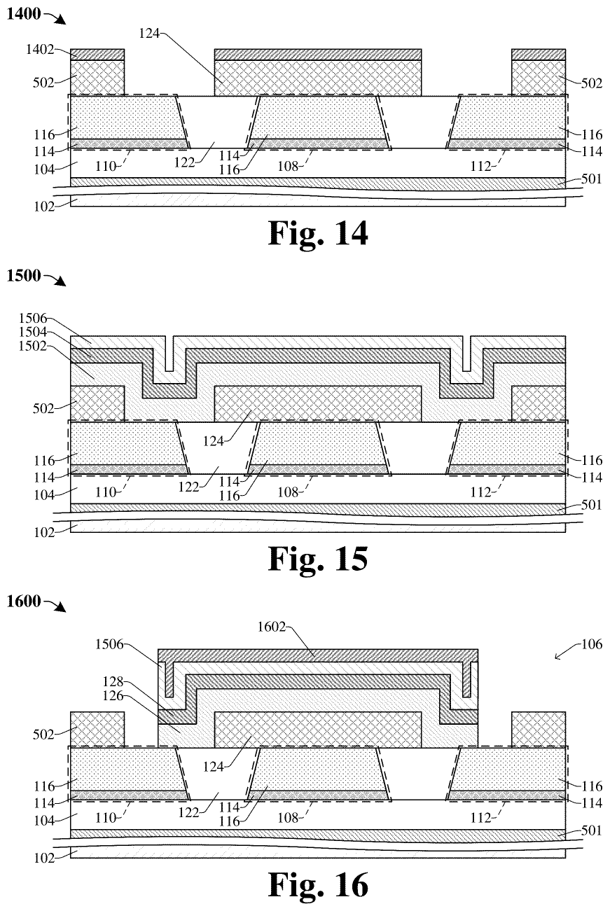

FIG. 7 illustrates a cross-sectional view 700 of some embodiments of an integrated chip including a PCM switch 106 arranged in an interconnect structure 701. In some embodiments, the PCM switch 106 is configured as illustrated and/or described in FIGS. 1-3. In alternative embodiments, the PCM switch 106 is configured as illustrated and/or described in any of FIGS. 5A-5C. Further, it will be appreciated that the cross-sectional view 700 is taken along a length of the heater structure 108, where the first and second electrodes (110, 112 of FIG. 1) are out of view. In various embodiments, the first and second electrodes (110, 112 of FIG. 1) are arranged on opposing sides of the heater structure 108 out of view of the cross-sectional view 700.

The interconnect structure 701 overlies the substrate 102. A plurality of semiconductor devices 702 are arranged on the substrate 102. The semiconductor devices 702 may, for example, be or comprise planar metal-oxide semiconductor field-effect transistors (MOSFETs). In some embodiments, the semiconductor devices 702 may be fin FETs (FinFETs), gate-all-around FETs (GAAFETs), gate-surrounding FETs, multi-bridge channel FETs (MBCFETs), nanowire FETs, nanoring FETs, nanosheet FETs (NSFETs), some other suitable transistor, or any combination of the foregoing. The semiconductor devices 702 may each comprise a gate electrode 724, a gate dielectric layer 722, and a pair of source/drain regions 720. The gate electrode 724 overlies the gate dielectric layer 722. The pair of source/drain regions 720 are arranged on opposing sides of the gate electrode 724. Source/drain region(s) may refer to a source or a drain, individually or collectively dependent upon the context.

The interconnect structure 701 comprises a plurality of metallization layers disposed within a dielectric structure. In some embodiments, the plurality of metallization layers comprises a plurality of conductive contacts 708, a plurality of conductive wires 710, and a plurality of conductive vias 712. The plurality of conductive wires 710 are arranged in a plurality of wire levels, and the plurality are arranged in a plurality of via levels that are alternatingly stacked with the plurality of wire levels. The dielectric structure surrounds the plurality of metallization layers and comprises a plurality of interconnect dielectric layers 706 and a plurality of etch stop layers 705. The plurality of interconnect dielectric layers 706 are alternatingly stacked with the plurality of etch stop layers 705.

In some embodiments, the plurality of conductive contact 708, the plurality of conductive wires 710, and the plurality of conductive vias 712 may, for example, be or comprise aluminum, copper, tungsten, ruthenium, some other conductive material, or any combination of the foregoing. In some embodiments, the plurality of interconnect dielectric layers 706 may, for example, be or comprise an oxide (e.g., silicon dioxide), doped silicon oxide (e.g., carbon doped silicon oxide), borosilicate glass (BSG), phosphoric silicate glass (PSG), a low-k dielectric, some other dielectric, or any combination of the foregoing. In some embodiments, the plurality of etch stop layers 705 may, for example, be or comprise silicon nitride, silicon carbide, some other suitable dielectric, or the like.

In various embodiments, the plurality of conductive wires 710 and the plurality of conductive wires 712 comprise a conductive body (not shown) and a conductive liner (not shown) enclosing the conductive body. In some embodiments, the conductive liner extends along outer sidewalls and a bottom surface of the conductive body. In some embodiments, the conductive body may, for example, be or comprise copper, aluminum, copper aluminum, or some other suitable conductive material. In some embodiments, the conductive liner may, for example, be or comprise titanium nitride, tantalum nitride, or some other suitable conductive layer. The conductive liner may, for example, be configured as a diffusion barrier layer.

The PCM switch 106 is disposed in the interconnect structure 701. In some embodiments, the PCM switch 106 is between a fifth wire level 715 of the plurality of conductive wires 710 and a sixth wire level 717 of the plurality of conductive wires 710. In other embodiments, the PCM switch 106 is vertically between two other wire levels that vertically neighbor each other in the interconnect structure 701. The interconnect structure 701 is electrically coupled to the PCM switch 106 and is configured to route signals (e.g., RF signals) between the first and second electrodes (not shown) of the PCM switch 106. Further, the interconnect structure 701 is configured to bias the heater structure 108 to control the heater structure 108 selectively heating the PCM structure 126.

A heat sink structure 714 is arranged in the interconnect structure 701 and under the heater structure 108. In some embodiments, the heat sink structure 714 comprises one or more conductive wires 710 and/or one or more conductive vias 712. The heat sink structure 714 is configured to dissipate heat while performing switching operations on the PCM switch 106. For example, the heat sink structure 714 may assist in cooling the PCM structure 126 while setting the PCM switch 106 to the “OFF” state.

In some embodiments, a conductive pad 713 is arranged in the interconnect structure 701. In some embodiments, the conductive pad 713 is arranged in the fifth wire level 715. In various embodiments, when viewed in top view, an area of the conductive pad 713 is at least 5,000 times greater than an area of the gate electrode 724 of a first semiconductor device 702 a in the plurality of semiconductor devices 702. The conductive pad 713 is electrically coupled to the gate electrode 724 of the first semiconductor device 702a. In other embodiments, the conductive pad 713 may be omitted.

During fabrication of the heater structure 108, the buffer layer 114 is deposited followed by the conductive layer 116 in a single processing chamber. During this process, a carrier gas (e.g., argon) and a precursor gas (e.g., nitrogen) are flowed in the processing chamber and a deposition process (e.g., PVD) is performed to deposit the buffer layer 114. After the buffer layer 114 is deposited, the flow of the precursor gas is stopped, but flowing of the carrier gas is continued and the conductive layer 116 is deposited (e.g., by PVD). The precursor gas (e.g., nitrogen) reduces a plasma sheath potential over the substrate 102, even after its flow is stopped (e.g., during deposition of the conductive layer 116), and decreases bombardment from the carrier gas, thereby decreasing PID. As a result, an accumulation of charge in the conductive pad 713 (and other metallization layers in the interconnect structure 701), due to a relatively high power applied to an RF generator that is configured to generate a plasma during deposition of the buffer layer 114 and/or the conductive layer 116, is reduced. In various embodiments, the area of the conductive pad 713 is substantially greater (e.g., at least 5,000 times greater) than the area of the gate electrode 724 of the first semiconductor device 702a to collect charge carriers during fabrication of the heater structure 108. By virtue of the buffer layer 114 comprising nitrogen, the accumulation of charge carriers in the conductive pad 713 is relatively low, such that the gate dielectric layer 722 does not undergo breakdown. Thus, the buffer layer 114 mitigates damage to the plurality of semiconductor devices 702, thereby increasing a performance of the integrated chip.

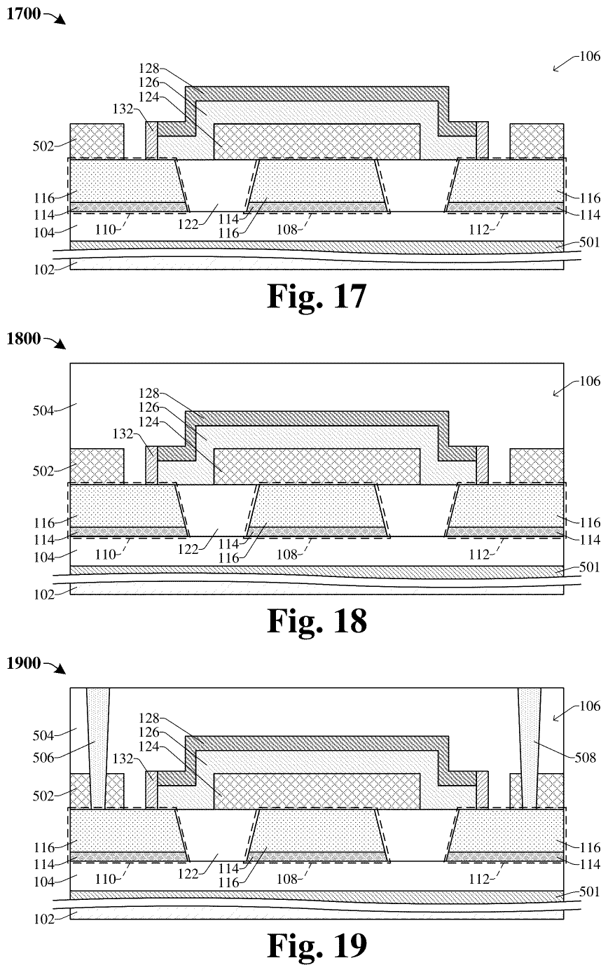

FIGS. 8-19 illustrate a series of cross-sectional views 800-1900 of some embodiments of a method of forming an integrated chip including a PCM switch with a heater structure comprising a buffer layer. Although the cross-sectional views 800-1900 shown in FIGS. 8-19 are described with reference to a method of forming the integrated chip, it will be appreciated that the structures shown in FIGS. 8-19 are not limited to the method of formation but rather may stand alone separate of the method. Further, although FIGS. 8-19 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 800 of FIG. 8, a substrate 102 is provided and an etch stop layer 501 and a first dielectric layer 104 are deposited over the substrate 102. The etch stop layer 501 is deposited over the substrate 102 by, for example, chemical vapor deposition (CVD), atomic layer deposition (ALD), or some other suitable growth or deposition process. The first dielectric layer 104 is deposited over the etch stop layer 501 by, for example, CVD, ALD, or some other suitable growth or deposition process. In some embodiments, the etch stop layer 501 may, for example, be or comprise silicon carbonitride, silicon nitride, silicon carbide, some other suitable dielectric material, or any combination of the foregoing. In some embodiments, the first dielectric layer 104 may, for example, be or comprise an oxide (e.g., silicon dioxide), some other suitable dielectric, or any combination of the foregoing.

As shown in cross-sectional view 900 of FIG. 9, a stack of layers 902 is formed over the first dielectric layer 104 and a hard mask layer 904 is formed on the stack of layers 902. In some embodiments, the stack of layers 902 includes a buffer layer 114 on the first dielectric layer 104 and a conductive layer 116 on the buffer layer 114. In various embodiments, the buffer layer 114 is deposited over the first dielectric layer 104 by, for example, CVD, ALD, physical vapor deposition (PVD), or some other suitable growth or deposition process. In some embodiments, the conductive layer 116 is deposited over the buffer layer 114 by, for example, CVD, ALD, PVD, or some other suitable growth or deposition process. In some embodiments, the hard mask layer 904 is deposited over the stack of layers 902 by, for example, CVD, PVD, ALD, or some other suitable growth or deposition process. In some embodiments, the hard mask layer 904 may, for example, be or comprise silicon dioxide, some other suitable dielectric, or any combination of the foregoing and may be formed with a thickness of about 500 angstroms, within a range of 400 to 600 angstroms, or some other suitable value. In various embodiments, the conductive layer 116 comprises a first metal (e.g., tungsten) and the buffer layer 114 comprises a nitride of the first metal (e.g., tungsten nitride).

In some embodiments, a deposition process for forming the stack of layers 902 over the first dielectric layer 104 includes: 1) loading the substrate 102 into a processing chamber; 2) setting the processing chamber to a first pressure (e.g., within a range of about 10⁻⁸ to 10⁻⁷ torr); 3) continuously flowing a carrier gas (e.g., argon) and a precursor gas (e.g., nitrogen (N₂)) into the processing chamber while maintaining a second pressure (e.g., within a range of about 10⁻⁷ to 10⁻⁶ torr) in the processing chamber; 4) performing a first PVD process in the processing chamber while flowing the carrier gas and the precursor gas to deposit the buffer layer 114 on the first dielectric layer 104; and 5) stop flowing the precursor gas, while continuing the flow of the carrier gas, and performing a second PVD process in the processing chamber to deposit the conductive layer 116 on the buffer layer 114. In various embodiments, steps 3-5 of the aforementioned deposition process may be repeated multiple times, without breaking the second pressure on the processing chamber, such that the stack of layers 902 comprises a plurality of buffer layers 114 alternatingly stacked with a plurality of conductive layers 116.

In some embodiments, the precursor gas (e.g., nitrogen (N₂)) is flowed into the processing chamber at a first flow rate of less than about 10 sccm, within a range of about 1 to 10 sccm, or some other suitable value. In further embodiments, the carrier gas (e.g., argon) is flowed into the processing chamber at a second flow rate of about 100 sccm, within a range of about 80 to 120 sccm, or some other suitable value. In some embodiments, the first flow rate of the precursor gas during the first PVD process is less than the second flow rate of the carrier gas. In further embodiments, a ratio of the first flow rate of the precursor gas (e.g., nitrogen (N₂)) and the second flow rate of the carrier gas (e.g., argon) is equal to or less than about 0.08, within a range of about 0.02 to 0.08, or some other suitable value.

In various embodiments, the first and second flow rates are set during the first PVD process such that the buffer layer 114 comprises a first atomic percent of nitrogen and a second atomic percent of tungsten that is greater than the first atomic percent. In some embodiments, the deposition process is performed such that the first atomic percent of nitrogen in the buffer layer 114 is about 1 at %, about 1.5 at %, within a range of about 0.5 at % to 8.5 at %, within a range of about 8.5 at % to 18 at %, within a range of about 0.5 at % to 18 at %, or some other suitable value. In various embodiments, by virtue of the ratio of the first flow rate of the precursor gas (e.g., nitrogen (N₂)) and the second flow rate of the carrier gas (e.g., argon) being within the range of about 0.02 to 0.08, the first atomic percent of nitrogen in the buffer layer 114 is within the range of about 0.5 at % to 18 at %. In yet further embodiments, the first PVD process is performed such that the buffer layer 114 is formed with a thickness within a range of about 10 to 400 angstroms or some other suitable value. In some embodiments, the conductive layer 116 is formed with a thickness greater than the thickness of the buffer layer 114. In various embodiments, the thickness of the conductive layer 116 is within a range of about 600 to 2,500 angstroms or some other suitable value. In some embodiments, the buffer layer 114 having a relatively low atomic percent of nitrogen (e.g., equal to or less than about 18 at %) and a relatively low thickness (e.g., equal to or less than about 400 angstroms) facilitates the buffer layer 114 providing a good atomic structural foundation to form the conductive layer 116 with a crystalline structure and relatively large grain sizes. As a result, the conductive layer 116 has a low electrical resistivity and an overall resistivity of the stack of layers 902 is relatively low (e.g., less than about 10 μΩ*cm, about 8.8 μΩ*cm, etc.).

In various embodiments, the deposition process may comprise providing between about 50 to 300 Watts (W) to a radio frequency (RF) generator to generate a plasma inside the processing chamber during the first and/or second PVD processes. In various embodiments, the precursor gas (e.g., nitrogen (N₂)) may reduce a plasma sheath potential over the substrate 102 during the deposition process, even after the flow of the precursor gas is stopped (e.g., during the second PVD process), and may decrease ion bombardment from the carrier gas, thereby decreasing plasma induced damage (PID) over the substrate 102. As a result, an accumulation of charge in metallization layers (e.g., conductive wires and/or vias) under the stack of layers 902, is reduced. Accordingly, leak current and/or gate dielectric breakdown of transistors disposed on the substrate 102 may be reduced.

As shown in cross-sectional view 1000 of FIG. 10, a first patterning process is performed on the stack of layers (902 of FIG. 9) and the hard mask layer 904 to form a first electrode 110, a second electrode 112, and a heater structure 108 spaced between the first electrode 110 and the second electrode 112. The stack of layers (902 of FIG. 9) may, for example, be patterned such that the first and second electrodes 110, 112 and the heater structure 108 each have a layout as illustrated and/or described in FIG. 2.

In some embodiments, the first patterning process includes: forming a first mask 1002 over the hard mask layer 904 (e.g., by a photolithography process); performing an etching process (e.g., a dry etch) on the stack of layers (902 of FIG. 9) and the hard mask layer 904 with the first mask 1002 in place; and performing a removal process to remove the first mask 1002 and the hard mask layer 904. In some embodiments, the heater structure 108, the first electrode 110, and the second electrode 112 each comprise the buffer layer 114 and the conductive layer 116. In various embodiments, the heater structure 108 is formed concurrently with the first and second electrodes 110, 112.

As shown in cross-sectional view 1100 of FIG. 11, a second dielectric layer 122 is deposited over and around the heater structure 108 and the first and second electrodes 110, 112. The second dielectric layer 122 may, for example, be deposited by CVD, ALD, or some other suitable growth or deposition process.

As shown in cross-sectional view 1200 of FIG. 12, a planarization process is performed on the second dielectric layer 122. In some embodiments, the planarization process is or comprises a chemical mechanical planarization (CMP) process and/or some other suitable planarization process. In various embodiments, after the planarization process, a top surface of the second dielectric layer 122 is aligned with top surfaces of the first and second electrodes 110, 112 and a top surface of the heater structure 108.

As shown in cross-sectional view 1300 of FIG. 13, a thermal barrier layer 1302 is deposited over the heater structure 108 and the first and second electrodes 110, 112. The thermal barrier layer 1302 may, for example, be deposited by CVD, PVD, ALD, or some other suitable growth or deposition process. In some embodiments, the thermal barrier layer 1302 may, for example, be or comprise silicon nitride, silicon carbide, aluminum nitride, some other suitable material, or any combination of the foregoing.

As shown in cross-sectional view 1400 of FIG. 14, a second patterning process is performed on the thermal barrier layer (1302 of FIG. 13) to form a thermal barrier structure 124 over the heater structure 108 and a passivation layer 502 over the first and second electrodes 110, 112. In some embodiments, the second patterning process includes: forming a second mask 1402 over the thermal barrier layer (1302 of FIG. 13) (e.g., by a photolithography process); performing an etching process (e.g., a dry etch) on the thermal barrier layer (1302 of FIG. 13) with the second mask 1402 in place; and performing a removal process to remove the second mask 1402.

As shown in cross-sectional view 1500 of FIG. 15, a PCM layer 1502, a first hard mask layer 1504, and a second hard mask layer 1506 are deposited over the thermal barrier structure 124 and the passivation layer 502. The PCM layer 1502 overlies the thermal barrier structure 124, the first hard mask layer 1504 overlies the PCM layer 1502, and the second hard mask layer 1506 overlies the first hard mask layer 1504. In some embodiments, the PCM layer 1502, the first hard mask layer 1504, and the second hard mask layer 1506 may each be deposited by an individual deposition process such as a CVD process, a PVD process, an ALD process, or some other suitable growth or deposition process. The PCM layer 1502 may, for example, be or comprise germanium antimony telluride, germanium telluride, vanadium oxide, some other suitable phase change material, or any combination of the foregoing. In some embodiments, the first hard mask layer 1504 comprises a first material (e.g., silicon nitride, silicon carbide, etc.) and the second hard mask layer 1506 comprises a second material (e.g., silicon dioxide or some other suitable oxide) different from the first material.

As shown in cross-sectional view 1600 of FIG. 16, a third patterning process is performed on the PCM layer (1502 of FIG. 15), the first hard mask layer (1504 of FIG. 15), and the second hard mask layer 1506. The third patterning process forms a PCM structure 126 over the heater structure 108 and a hard mask 128 over the PCM structure 126. In some embodiments, the third patterning process includes: forming a third mask 1602 over the second hard mask layer 1506 (e.g., by a photolithography process); performing an etching process (e.g., a dry etch) on the PCM layer (1502 of FIG. 15), the first hard mask layer (1504 of FIG. 15), and the second hard mask layer 1506 with the third mask 1602 in place; and performing a removal process to remove the third mask 1602 and the second hard mask layer 1506. The PCM structure 126, the thermal barrier structure 124, the first and second electrodes 110, 112, and the heater structure 108 form a PCM switch 106.

As shown in cross-sectional view 1700 of FIG. 17, a sidewall spacer 132 is formed along sidewalls of the PCM structure 126 and the hard mask 128. In some embodiments, forming the sidewall spacer 132 includes depositing (e.g., by CVD, PVD, ALD, etc.) a sidewall spacer layer over the PCM structure 126 and the hard mask 128, and etching the sidewall spacer layer. The sidewall spacer 132 may, for example, be or comprise silicon nitride, silicon carbide, some other dielectric material, or any combination of the foregoing.

As shown in cross-sectional view 1800 of FIG. 18, a third dielectric layer 504 is deposited over the hard mask 128. In some embodiments, the third dielectric layer 504 is deposited by CVD, ALD, or some other suitable growth or deposition process. The third dielectric layer 504 may, for example, be or comprise silicon dioxide, some other dielectric material, or any combination of the foregoing.

As shown in cross-sectional view 1900 of FIG. 19, a plurality of conductive vias 506, 508 are formed in the third dielectric layer 504 and over the first and second electrodes 110, 112. In various embodiments, one or more conductive vias are formed over the heater structure 108 in a region outside of the cross-sectional view 1900 of FIG. 19. In some embodiments, forming the plurality of conductive vias 506, 508 includes: patterning the third dielectric layer 504 and the passivation layer 502 to form one or more openings over the first and second electrodes 110, 112 and the heater structure 108; filling the one or more openings with one or more conductive materials (e.g., copper, aluminum, titanium nitride, tantalum nitride, etc.); and performing a planarization process (e.g., a CMP process) on the one or more conductive materials.

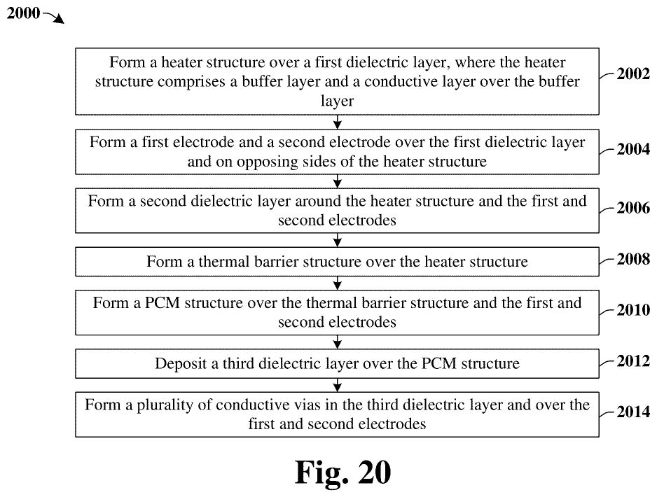

FIG. 20 illustrates a block diagram of some embodiments of a method 2000 of forming an integrated chip including a PCM switch with a heater structure having a buffer layer. Although the method 2000 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2002, a heater structure is formed over a first dielectric layer. The heater structure comprises a buffer layer and a conductive layer over the buffer layer. FIGS. 9 and 10 illustrate the cross-sectional views 900 and 1000 corresponding to some embodiments of act 2002.

At act 2004, a first electrode and a second electrode are formed over the first dielectric layer and on opposing sides of the heater structure. FIGS. 9 and 10 illustrate the cross-sectional views 900 and 1000 corresponding to some embodiments of act 2004.

At act 2006, a second dielectric is formed around the heater structure and the first and second electrodes. FIGS. 11 and 12 illustrate the cross-sectional views 1100 and 1200 corresponding to some embodiments of act 2006.

At act 2008, a thermal barrier structure is formed over the heater structure. FIGS. 13 and 14 illustrate the cross-sectional views 1300 and 1400 corresponding to some embodiments of act 2008.

At act 2010, a PCM structure is formed over the thermal barrier structure and the first and second electrodes. FIGS. 15 and 16 illustrate the cross-sectional views 1500 and 1600 corresponding to some embodiments of act 2010.

At act 2012, a third dielectric layer is deposited over the PCM structure. FIG. 18 illustrates the cross-sectional view 1800 corresponding to some embodiments of act 2012.

At act 2014, a plurality of conductive vias are formed in the third dielectric layer and over the first and second electrodes. FIG. 19 illustrates the cross-sectional view 1900 corresponding to some embodiments of act 2014.

Accordingly, in some embodiments, the present application relates to a PCM switch with a heater structure that comprises a buffer layer and a conductive layer overlying the buffer layer.

In various embodiments, the present application provides an integrated chip, including: a first dielectric layer over a substrate; a phase change material (PCM) structure over the first dielectric layer; and a heater structure in the first dielectric layer and under the PCM structure, wherein the heater structure includes a first buffer layer and a first conductive layer on the first buffer layer, wherein the first conductive layer comprises a metal, wherein the first buffer layer comprises the metal and a first element different from the metal, wherein a first atomic percent of the first element in the first buffer layer is less than a second atomic percent of the metal in the first buffer layer. In some embodiments, the first atomic percent is less than or equal to 18 at %. In some embodiments, a thickness of the first buffer layer is less than a thickness of the first conductive layer. In some embodiments, outer sidewalls of the first buffer layer are aligned with outer sidewalls of the first conductive layer. In some embodiments, the integrated chip further includes a thermal barrier structure between the PCM structure and the heater structure, wherein a width of the thermal barrier structure is greater than a width of the heater structure. In some embodiments, a thickness of the thermal barrier structure is greater than a thickness of the first buffer layer. In some embodiments, the integrated chip further includes a first electrode and a second electrode in the first dielectric layer and on opposing sides of the heater structure, wherein the PCM structure overlies the first electrode and the second electrode, wherein the first electrode and the second electrode each comprise a second buffer layer and a second conductive layer on the second buffer layer, wherein the second conductive layer comprises the metal and the second buffer layer comprises the metal and the first element. In some embodiments, a resistivity of the first buffer layer is greater than a resistivity of the first conductive layer. In some embodiments, the first conductive layer has a crystalline structure and the first buffer layer has an amorphous structure.

In various embodiments, the present application provides a method for forming an integrated chip, the method including: depositing a first dielectric layer over a substrate; depositing a stack of layers over the first dielectric layer, wherein the stack of layers comprises a buffer layer over the first dielectric layer and a conductive layer over the buffer layer, wherein the conductive layer comprises a metal and the buffer layer comprises a nitride of the metal, wherein an atomic percent of nitrogen in the buffer layer is less than 50 at %, and wherein a thickness of the buffer layer is less than a thickness of the conductive layer; etching the stack of layers to form a heater structure and a pair of electrodes over the first dielectric layer, wherein the pair of electrodes is on opposing sides of the heater structure, wherein the heater structure comprises the buffer layer and the conductive layer; depositing a phase change material (PCM) layer over the heater structure; and etching the PCM layer to form a PCM structure over the heater structure. In some embodiments, the method further includes forming a thermal barrier structure on the heater structure, wherein the thermal barrier structure is arranged between the heater structure and the PCM structure, wherein a width of the thermal barrier structure is greater than a width of a middle segment of the heater structure spaced laterally between the pair of electrodes. In some embodiments, the method further includes forming a second dielectric layer over the first dielectric layer and around the heater structure, wherein the second dielectric layer extends laterally between the heater structure and the pair of electrodes, wherein a top surface of the second dielectric layer is aligned with a top surface of the conductive layer. In some embodiments, the thickness of the buffer layer is equal to or less than 400 angstroms. In some embodiments, the heater structure is formed concurrently with the pair of electrodes. In some embodiments, the PCM structure contacts an outer region of a top surface of a first electrode in the pair of electrodes and contacts an outer region of a top surface of a second electrode in the pair of electrodes.

In various embodiments, the present application provides a method for forming an integrated chip, the method including: depositing a first dielectric layer over a substrate; depositing a stack of layers over the first dielectric layer, wherein the stack of layers comprises a buffer layer on the first dielectric layer and a conductive layer on the buffer layer, wherein the conductive layer comprises a metal and the buffer layer comprises a nitride of the metal, wherein a majority of a chemical composition of the buffer layer comprises the metal; patterning the stack of layers to form a heater structure, a first electrode, and a second electrode, wherein the heater structure is spaced laterally between the first electrode and the second electrode; depositing a thermal barrier layer over the heater structure; patterning the thermal barrier layer to form a thermal barrier structure on the heater structure; depositing a phase change material (PCM) layer over the thermal barrier structure; depositing a hard mask layer over the PCM layer; and patterning the PCM layer and the hard mask layer to form a PCM structure over the thermal barrier structure and a hard mask over the PCM structure. In some embodiments, depositing the stack of layers includes: flowing a carrier gas and a precursor gas at a first pressure; performing a first physical vapor deposition (PVD) while flowing the carrier gas and the precursor gas to deposit the buffer layer on the first dielectric layer; and performing a second PVD process while flowing the precursor gas to deposit the conductive layer on the buffer layer, wherein the flow of the precursor gas is stopped before and during the second PVD process. In some embodiments, the first pressure is within a range of about 10⁻⁷ to 10⁻⁶ torr. In some embodiments, a first flow rate of the precursor gas during the first PVD is less than a second flow rate of the carrier gas during the first PVD. In some embodiments, a ratio of the first flow rate and the second flow rate is equal to or less than about 0.08.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a first dielectric layer over a substrate;
a phase change material (PCM) structure over the first dielectric layer; and
a heater structure in the first dielectric layer and under the PCM structure, wherein the heater structure comprises a first buffer layer and a first conductive layer on the first buffer layer, wherein the first conductive layer comprises a metal, wherein the first buffer layer comprises the metal and a first element different from the metal, wherein a first atomic percent of the first element in the first buffer layer is less than a second atomic percent of the metal in the first buffer layer.

2. The integrated chip of claim 1, wherein the first atomic percent is less than or equal to 18 at %.

3. The integrated chip of claim 1, wherein a thickness of the first buffer layer is less than a thickness of the first conductive layer.

4. The integrated chip of claim 1, wherein outer sidewalls of the first buffer layer are aligned with outer sidewalls of the first conductive layer.

5. The integrated chip of claim 1, further comprising:
a thermal barrier structure between the PCM structure and the heater structure, wherein a width of the thermal barrier structure is greater than a width of the heater structure.

6. The integrated chip of claim 5, wherein a thickness of the thermal barrier structure is greater than a thickness of the first buffer layer.

7. The integrated chip of claim 1, further comprising:
a first electrode and a second electrode in the first dielectric layer and on opposing sides of the heater structure, wherein the PCM structure overlies the first electrode and the second electrode, wherein the first electrode and the second electrode each comprise a second buffer layer and a second conductive layer on the second buffer layer, wherein the second conductive layer comprises the metal and the second buffer layer comprises the metal and the first element.

8. The integrated chip of claim 1, wherein a resistivity of the first buffer layer is greater than a resistivity of the first conductive layer.

9. The integrated chip of claim 1, wherein the first conductive layer has a crystalline structure and the first buffer layer has an amorphous structure.

10. A method for forming an integrated chip, comprising:
depositing a first dielectric layer over a substrate;
depositing a stack of layers over the first dielectric layer, wherein the stack of layers comprises a buffer layer over the first dielectric layer and a conductive layer over the buffer layer, wherein the conductive layer comprises a metal and the buffer layer comprises a nitride of the metal, wherein an atomic percent of nitrogen in the buffer layer is less than 50 at %, and wherein a thickness of the buffer layer is less than a thickness of the conductive layer;
etching the stack of layers to form a heater structure and a pair of electrodes over the first dielectric layer, wherein the pair of electrodes is on opposing sides of the heater structure, wherein the heater structure comprises the buffer layer and the conductive layer;
depositing a phase change material (PCM) layer over the heater structure; and
etching the PCM layer to form a PCM structure over the heater structure.

11. The method of claim 10, further comprising:
forming a thermal barrier structure on the heater structure, wherein the thermal barrier structure is arranged between the heater structure and the PCM structure, wherein a width of the thermal barrier structure is greater than a width of a middle segment of the heater structure spaced laterally between the pair of electrodes.

12. The method of claim 10, further comprising:
forming a second dielectric layer over the first dielectric layer and around the heater structure, wherein the second dielectric layer extends laterally between the heater structure and the pair of electrodes, wherein a top surface of the second dielectric layer is aligned with a top surface of the conductive layer.

13. The method of claim 10, wherein the thickness of the buffer layer is equal to or less than 400 angstroms.

14. The method of claim 10, wherein the heater structure is formed concurrently with the pair of electrodes.

15. The method of claim 10, wherein the PCM structure contacts an outer region of a top surface of a first electrode in the pair of electrodes and contacts an outer region of a top surface of a second electrode in the pair of electrodes.

16. A method for forming an integrated chip, comprising:
depositing a first dielectric layer over a substrate;
depositing a stack of layers over the first dielectric layer, wherein the stack of layers comprises a buffer layer on the first dielectric layer and a conductive layer on the buffer layer, wherein the conductive layer comprises a metal and the buffer layer comprises a nitride of the metal, wherein a majority of a chemical composition of the buffer layer comprises the metal;
patterning the stack of layers to form a heater structure, a first electrode, and a second electrode, wherein the heater structure is spaced laterally between the first electrode and the second electrode;
depositing a thermal barrier layer over the heater structure;
patterning the thermal barrier layer to form a thermal barrier structure on the heater structure;
depositing a phase change material (PCM) layer over the thermal barrier structure;
depositing a hard mask layer over the PCM layer; and
patterning the PCM layer and the hard mask layer to form a PCM structure over the thermal barrier structure and a hard mask over the PCM structure.

17. The method of claim 16, wherein depositing the stack of layers comprises:
flowing a carrier gas and a precursor gas at a first pressure;
performing a first physical vapor deposition (PVD) while flowing the carrier gas and the precursor gas to deposit the buffer layer on the first dielectric layer; and
performing a second PVD process while flowing the precursor gas to deposit the conductive layer on the buffer layer, wherein the flow of the precursor gas is stopped before and during the second PVD process.

18. The method of claim 17, wherein the first pressure is within a range of about 10⁻⁷ to 10⁻⁶ torr.

19. The method of claim 17, wherein a first flow rate of the precursor gas during the first PVD is less than a second flow rate of the carrier gas during the first PVD.

20. The method of claim 19, wherein a ratio of the first flow rate and the second flow rate is equal to or less than about 0.08.
